(19) United States
(12) Patent Application Publication
(10) Pub. No.: US 2025/0280629 A1
(43) Pub. Date: Sep. 4, 2025

(54) LIGHT-EMITTING DIODE AND LIGHT-EMITTING DEVICE

(71) Applicant: Anhui Sanan Optoelectronics Co., Ltd., Wuhu (CN)

(72) Inventors: YU WANG, Wuhu (CN); YAWEI WANG, Wuhu (CN); HONGMIN ZHOU, Wuhu (CN); ZHIHAO CHEN, Wuhu (CN); CHAN-CHAN LING, Wuhu (CN); CHENG-HUNG LEE, Wuhu (CN)

(21) Appl. No.: 18/810,564

(22) Filed: Aug. 21, 2024

(30) Foreign Application Priority Data
Aug. 23, 2023 (CN) 2023110694732

(51) Int. Cl. H10H 20/821; H10H 20/812

(52) U.S. Cl. CPC H10H 20/821; H10H 20/812

(57) ABSTRACT

A light-emitting diode includes a first semiconductor layer, a V-pit formation layer, a light-emitting layer and a second semiconductor layer. The light-emitting layer includes a first light-emitting layer and a second light-emitting layer, the first light-emitting layer includes n1 periods of a first quantum well structure, the second light-emitting layer includes n2 periods of a second quantum well structure, the first light-emitting layer or the second light-emitting layer further includes m periods of a third quantum well structure, and the third quantum well structure has a greater thickness than other quantum well structures located in the light-emitting layer. The above structure can effectively improve the quality of the V-pit, reduce the probability of non-radiative recombination and ensure the effective electron-hole recombination efficiency in the LED.

### CROSS-REFERENCE TO RELATED APPLICATIONS

This application claims priority to Chinese patent application No. 202311069473.2, filed on Aug. 23, 2023, which is herein incorporated by reference in its entirety.

### TECHNICAL FIELD

The disclosure relates to the field of semiconductor technologies, and more particularly to a light-emitting diode (LED) and a light-emitting device.

### BACKGROUND

Light-emitting diodes (LEDs) are commonly used light-emitting devices that can efficiently convert electric energy into light energy by combining electrons and holes to emit light. LEDs typically employ various semiconductor materials and structures to achieve a full spectrum of colors from ultraviolet to infrared.

With the continuous development of LED industry, customers' demands for the photoelectric performance (brightness and voltage) of LEDs are increasingly high. Currently, V-pits (also referred to as V-shaped pits) are commonly used to improve the epitaxial performance. However, the formation of the V-pits has always been an industry challenge, as their position, size, and quality are all related to the performance of LEDs. The quality of the V-pits in existing LEDs is poor, leading to the formation of more non-radiative recombination centers, which affects the electron-hole recombination efficiency.

### SUMMARY

In view of the shortcomings of the related art mentioned above, the purpose of the disclosure is to provide a LED and a light-emitting device that improve the quality of V-pits and reduce non-radiative recombination.

According to a first aspect of the disclosure, the disclosure provides a LED, including:
a first semiconductor layer;
a V-pit formation layer, located on the first semiconductor layer, and the V-pit formation layer defining an upwardly extending V-pit;
a light-emitting layer, located on the V-pit formation layer; and
a second semiconductor layer, located on the light-emitting layer and filling the V-pit;
where the light-emitting layer includes:
   a first light-emitting layer, including n1 periods of a first quantum well structure and m periods of a third quantum well structure, where a thickness of a single period of the third quantum well structure is greater than that of a single period of the first quantum well structure; and
   a second light-emitting layer, closer to the second semiconductor layer than the first light-emitting layer, where the second light-emitting layer includes n2 periods of a second quantum well structure.

According to a second aspect of the disclosure, the disclosure provides another LED, including:
a first semiconductor layer;
a V-pit formation layer, located on the first semiconductor layer, and the V-pit formation layer defining an upwardly extending V-pit;
a light-emitting layer, located on the V-pit formation layer; and
a second semiconductor layer, located on the light-emitting layer and filling the V-pit;
where the light-emitting layer includes:
   a first light-emitting layer, including n1 periods of a first quantum well structure; and
   a second light-emitting layer, closer to the second semiconductor layer than the first light-emitting layer, where the second light-emitting layer includes n2 periods of a second quantum well structure and m periods of a third quantum well structure, and a thickness of a single period of the third quantum well structure is greater than that of a single period of the second quantum well structure.

According to a third aspect of the disclosure, the disclosure provides a light-emitting device, including the LED as described in any of the above.

The LED and the light-emitting device provided by embodiments of the disclosure can effectively improve the quality of the V-pit, reduce the probability of non-radiative recombination, and ensure the electron-hole recombination efficiency of the LED, thereby improving the brightness of the LEB, by providing the third quantum well structure with a larger thickness in the light-emitting layer.

### BRIEF DESCRIPTION OF DRAWINGS

FIG. 1 illustrates a schematic structural diagram of an epitaxial structure of a LED provided by some embodiments of the disclosure.

FIG. 2 illustrates a partial schematic structural diagram of an epitaxial structure of a LED provided by some embodiments of the disclosure.

FIG. 3 is a schematic structural diagram of an epitaxial structure with a mesa structure provided by some embodiments of the disclosure.

FIG. 4 is a schematic structural diagram of a LED provided by some embodiments of the disclosure.

FIG. 5 is an enlarged view of a portion A in FIG. 2.

FIG. 6 is an enlarged view of a portion A in FIG. 2.

FIG. 7 is an enlarged view of a portion A in FIG. 2.

FIG. 8 is an enlarged view of a portion A in FIG. 2.

### DETAILED DESCRIPTION OF EMBODIMENTS

A first embodiment of the disclosure provides a LED. As illustrated in FIG. 1, an epitaxial structure 1 of the LED may include a first semiconductor layer 20, a V-pit formation layer 30, a light-emitting layer 40 and a second semiconductor layer 50.

The epitaxial structure 1 of the LED can be composed of gallium nitride-based materials, gallium arsenide-based materials, etc., and element composition ratios of semiconductor layers can be adjusted to radiate a desired wavelength, such as providing ultraviolet, blue, green, yellow, red, infrared light and other light radiation. In the embodiment, the epitaxial structure 1 of the LED is made of the gallium nitride-based material, and the gallium nitride-based material includes but is not limited to gallium nitride (GaN), indium gallium nitride (InGaN), aluminium gallium nitride (AlGaN), and aluminium indium gallium nitride (AlInGaN).

The epitaxial structure 1 of the LED may be located on an upper surface of a substrate 80. The material of the substrate 80 includes one or more selected from the group consisting of sapphire (Al₂O₃), silicon dioxide (SiO₂), silicon carbide (SiC), gallium arsenide (GaAs), GaN, zinc oxide (ZnO), silicon (Si), gallium phosphide (GaP), indium phosphide (InP) and germanium (Ge), and the substrate 80 is a patterned substrate or a flat-sheet substrate. In the embodiment, a patterned sapphire substrate is taken as an example. It should be noted that the substrate 80 can eventually be thinned, and is not particularly limited here.

Specifically, in a direction facing away from the substrate 80, the first semiconductor layer 20, the V-pit formation layer 30, the light-emitting layer 40 and the second semiconductor layer 50 are sequentially stacked in that order. The first semiconductor layer 20 or the second semiconductor layer 50 may be n-type doped or p-type doped to provide electrons or holes. An n-type semiconductor layer may be doped with an n-type dopant such as Si, Ge, or stannum (Sn), and a p-type semiconductor layer may be doped with a p-type dopant such as magnesium (Mg), zinc (Zn), calcium (Ca), strontium (Sr), or barium (Ba). When the first semiconductor layer 20 is the n-type semiconductor layer, the second semiconductor layer 50 is the p-type semiconductor layer; or when the first semiconductor layer 20 is the p-type semiconductor layer, the second semiconductor layer 50 is the n-type semiconductor layer. In some alternative embodiments, the first semiconductor layer 20 is the n-type semiconductor layer, and the second semiconductor layer 50 is the p-type semiconductor layer; and preferably, the materials of the first semiconductor layer 20 and the second semiconductor layer 50 are both GaN.

The first semiconductor layer 20 and the second semiconductor layer 50 may have a single-layer structure or a multi-layer structure, and at least one layer of the first semiconductor layer 20 and at least one layer of the second semiconductor layer 50 are respectively n-type doped and p-type doped.

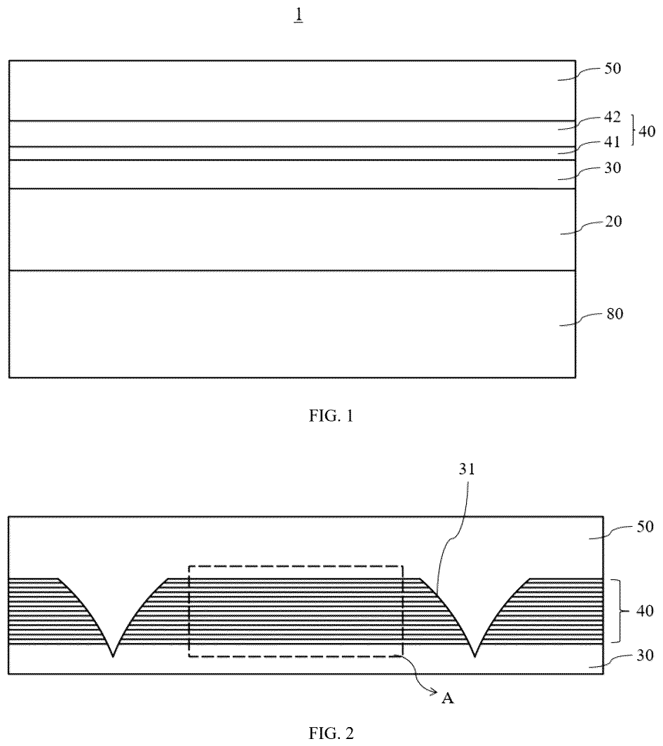

As illustrated in FIG. 2, the V-pit formation layer 30 is mainly used to form a V-pit 31, which is an initial formation layer of the V-pit 31. The setting of the V-pit 31 can release the stress during the growth process and can increase the brightness of the LED. The V-pit 31 formed by the V-pit formation layer 30 is an initial prototype, which will extend upward along the growth direction and penetrate the light-emitting layer, and will eventually be covered by the second semiconductor layer 50 to form a flat surface. Preferably, a thickness of the V-pit formation layer 30 is in the range of 500 angstroms (Å) to 2000 Å to ensure sufficient thickness to form the prototype of the V-pit 31.

In some alternative embodiments, the material of the V-pit formation layer 30 may be GaN, InGaN, AlGaN, AlInGaN, etc. In the embodiment, the material of the V-pit formation layer 30 is preferably GaN. Compared with the V-pit formation layer including Al material, the V-pit formation layer including GaN material is easier to film and shape, and is easier to form the V-pit 31. Compared with the V-pit formation layer including In material, the V-pit formation layer including GaN material is not easy to have the problem of double peak anomaly.

The light-emitting layer 40 is an actual light-emitting area of the LED. The electrons and holes provided by the first semiconductor layer 20 and the second semiconductor layer 50 will combine and undergo radiative recombination in the light-emitting layer 40 to achieve light emission.

As illustrated in FIGS. 1, 5 and 6, the light-emitting layer 40 includes a first light-emitting layer 41 and a second light-emitting layer 42. The second light-emitting layer 42 is closer to the second semiconductor layer 50 than the first light-emitting layer 41. In the embodiment, the second light-emitting layer 42 is located on the first light-emitting layer 41.

The light-emitting layer 40 is a multi-quantum well structure, in which the first light-emitting layer 41 includes n1 periods of a first quantum well structure 411 and m periods of a third quantum well structure 431, and the second light-emitting layer 42 includes n2 periods of a second quantum well structure 421.

In the embodiment, a thickness of the single period of the third quantum well structure 431 is greater than a thickness of the single period of the first quantum well structure 411. The main function of the third quantum well structure 431 is used to repair the quality of the V-pit 31 to reduce the probability of non-radiative recombination. Setting the thicker third quantum well structure 431 is more conducive to improving the quality of the V-pit 31.

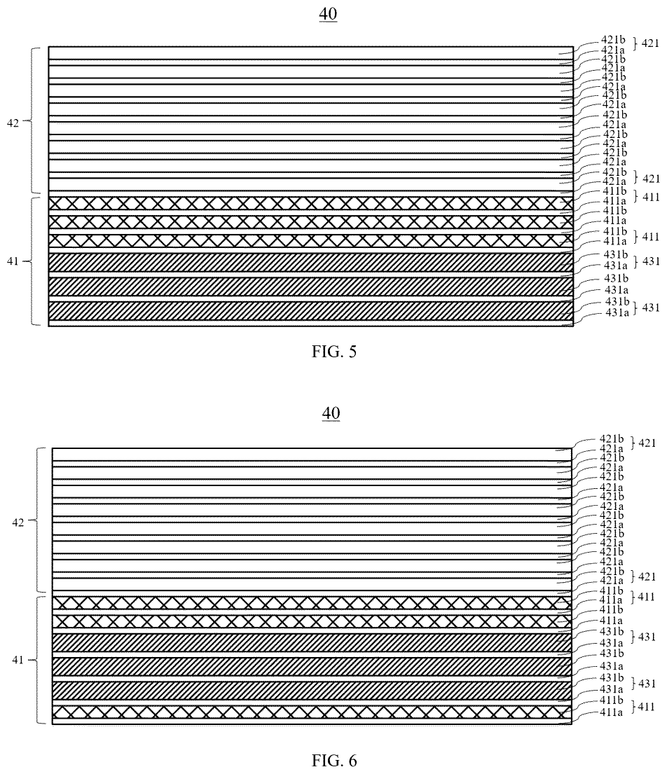

In some embodiments, the m periods of the third quantum well structure 431 can be disposed at any position in the first light-emitting layer 41, and may or may not be in direct contact with the V-pit formation layer 30, as illustrated in FIG. 5 and FIG. 6. Preferably, the m periods of the third quantum well structure 431 is close to the V-pit formation layer 30 so as to facilitate timely repair and improvement of the quality of the V-pit 31 and avoid the problem of limited repair effect due to too late installation. Further preferably, the m periods of the third quantum well structure 431 are arranged continuously rather than at intervals, that is, there are no other quantum well structures between two adjacent third quantum well structures 431. In other embodiments, the m periods of the third quantum well structure 431 may also be disposed between the first quantum well structures 411.

Further, the first quantum well structure 411 includes a first well layer 411a and a first barrier layer 411b, the second quantum well structure 421 includes a second well layer 421a and a second barrier layer 421b, and the third quantum well structure 431 includes a third well layer 431a and a third barrier layer 431b.

In some embodiments, a thickness of each of the first well layer 411a, the second well layer 421a and the third well layer 431a is in the range of 20 Å to 50 Å. A thickness of each of the first barrier layer 411b, the second barrier layer 421b and the third barrier layer 431b is in the range of 80 Å to 140 Å. Preferably, the thicknesses of the first well layer 411a, the second well layer 421a and the third well layer 431a are set to be same to avoid defects of different wavelengths caused by different thicknesses of the well layers, while the first barrier layer 411b, the second barrier layer 421b and the third barrier layer 431b can be set to different thicknesses, the thickness of the third barrier layer 431b is greater than the thickness of the first barrier layer 411b, which can better improve the quality of the V-pit 31 by setting the thicker third barrier layer 431b. Preferably, the thickness of the first barrier layer 411b is in the range of 80 Å to 110 Å, and the thickness of the third barrier layer 431b is in the range of 110 Å to 140 Å. More preferably, the thickness of the third barrier layer 431b is 1.1 to 1.5 times the thickness of the first barrier layer 411b. It should be noted that the thickness of the quantum well structure, the thickness of the well layer, and the thickness of the barrier layer described above refer to the thickness of the single quantum well structure, the thickness of the single well layer, and the thickness of the single barrier layer.

In some embodiments, the period numbers of the first quantum well structure 411, the second quantum well structure 421 and the third quantum well structure 431 are same or different, and the period numbers of the first quantum well structure 411, the second quantum well structure 421 and the third quantum well structure 431 are integer. Preferably, the period number n2 of the second quantum well structure 421 is greater than the period number n1 of the first quantum well structure 411. Further preferably, the period number n1 of the first quantum well structure 411 is in the range of 1 to 4, the period number n2 of the second quantum well structure 421 is in the range of 8 to 13, and the period number m of the third quantum well structure 431 is in the range of 1 to 4. More preferably, the period number m of the third quantum well structure 431 is not greater than the period number n1 of the first quantum well structure 411, that is, m≤n1, or in other words, the number of the third quantum well structures 431 cannot exceed half of the number of all quantum well structures in the first light-emitting layer 41.

In some embodiments, each well layer is a semiconductor material layer containing In, which can be represented by the molecular formula Inₓ₁Ga₁₋ₓ₁N, for example, where 0<x1<1, and each barrier layer is a semiconductor material layer with a larger band gap than the well layer, which can be represented by the molecular formula Al_{y2}Inₓ₂Ga_{1-x2-y2}N, for example, where 0≤x2≤1, 0≤y2≤1, and x2<x1. Preferably, the barrier layer is GaN or AlGaN, and the well layer is InGaN. In the embodiment, the first barrier layer 411b is a GaN layer, the first well layer 411a is an InGaN layer, the second barrier layer 421b is a AlGaN layer, the second well layer 421a is an InGaN layer, the third barrier layer 431b is a GaN layer, and the third well layer 431a is an InGaN layer. In some embodiments, the first barrier layer 411b is a GaN layer, the first well layer 411a is an InGaN layer, the second barrier layer 421b is a AlGaN layer, the second well layer 421a is an InGaN layer, the third barrier layer 431b is a AlGaN layer, and the third well layer 431a is an InGaN layer. Further preferably, In content of the first well layer 411a and In content of the second well layer 421a are same, and In content of the third well layer 431a is highest.

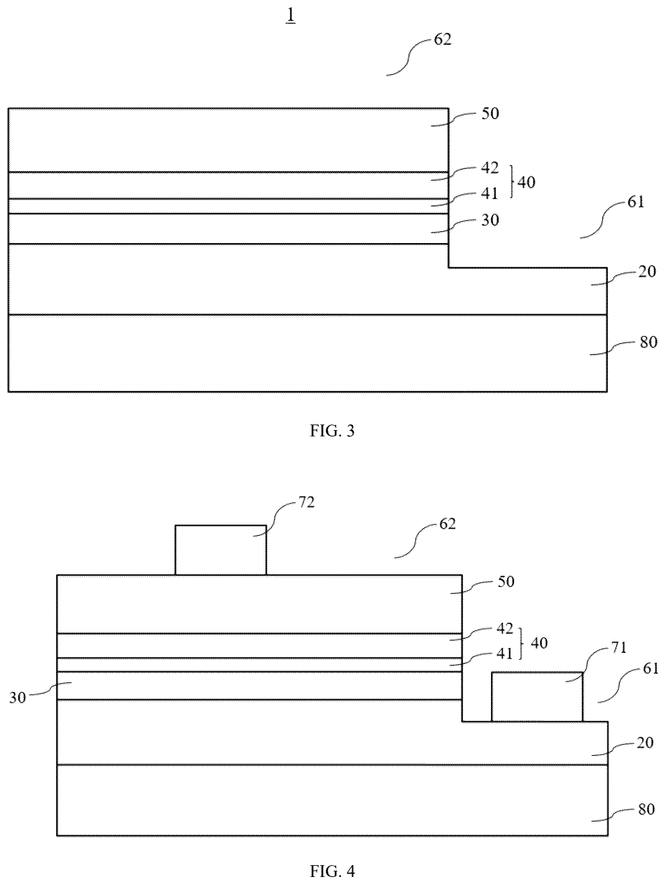

The LED provided by the first embodiment of the disclosure further includes a mesa structure and an electrode structure, as illustrated in FIGS. 3 and 4.

The mesa structure is generally referred to as MESA, and the mesa structure exposes part of the first semiconductor layer 20 to reserve an area for subsequent electrode fabrication. The mesa structure includes a lower mesa 61 and an upper mesa 62, the lower mesa 61 is the upper surface of the exposed portion of the first semiconductor layer 20, and the upper mesa 62 is the upper surface of the second semiconductor layer 50.

The electrode structure includes a first electrode 71 and a second electrode 72. The first electrode 71 is disposed on the lower mesa 61 and is electrically connected to the first semiconductor layer 20. The second electrode 72 is disposed on the upper mesa 62 and is electrically connected to the second semiconductor layer 20. Both the first electrode 71 and the second electrode 72 are metal electrodes, and the material of each of the first electrode 71 and the second electrode 72 is one or more selected from the group consisting of nickel (Ni), palladium (Pd), platinum (Pt), chromium (Cr), gold (Au), titanium (Ti), silver (Ag), aluminum (Al), germanium (Ge), tungsten (W), silicon tungsten (SiW), tantalum (Ta), gold zinc (AuZn), gold beryllium (AuBe), gold germanium (AuGe), and gold germanium nickel (AuGeNi).

An embodiment of the disclosure further provides a method for preparing the LED according to the first embodiment.

First, the epitaxial structure 1 is provided, which specifically includes the following steps: providing the substrate 80, and sequentially growing the first semiconductor layer 20, the V-pit formation layer 30, the light-emitting layer 40 and the second semiconductor layer 50 on the substrate 80.

Specifically, the first semiconductor layer 20, the V-pit formation layer 30, the light-emitting layer 40 and the second semiconductor layer 50 can be formed by physical vapor deposition (PVD), chemical vapor deposition (CVD), epitaxial growth, atomic beam deposition (ALD), etc. way to grow.

The V-pit formation layer 30 is grown at a low temperature to form the prototype of the V-pit 31 in this layer. The preferred growth temperature is in the range of 700° C. to 850° C., which is more conducive to the development of the V-pit 31. Specifically, the growth thickness of the V-pit formation layer 30 is in the range of 500 Å to 2000 Å.

The light-emitting layer 40 includes the first light-emitting layer 41 and the second light-emitting layer 42 grown sequentially. The first light-emitting layer 41 includes the n1 periods of the first quantum well structure 411 and the m periods of the third quantum well structure 431, and the second light-emitting layer 42 includes the n2 periods of the second quantum well structure 421. The first quantum well structure 411 includes the first well layer 411a and the first barrier layer 411b grown sequentially, the second quantum well structure 421 includes the second well layer 421a and the second barrier layer 421b grown sequentially, and the third quantum well structure 431 includes the third well layer 431a and the third barrier layer 431b grown sequentially.

During the process of growing the first light-emitting layer 41, all of the third quantum well structures 431 may be grown first, and then all of the first quantum well structures 411 may be grown, or part of the first quantum well structures 411 may be grown first, then all of the third quantum well structures 431 are grown, and finally the remaining first quantum well structures 411 are grown. The thickness of the single third quantum well structure 431 is greater than the thickness of the single first quantum well structure 411.

In each quantum well structure, the well layer and the barrier layer adopt different growth temperatures. Preferably, the well layer is grown at a relatively low temperature, and the barrier layer is grown at a relatively high temperature. Further preferably, the growth temperature of each of the first well layer 411a, the second well layer 421a and the third well layer 431a is in the range of 700° C. to 800° C., and the growth temperature of each of the first barrier layer 411b, the second barrier layer 421b and the third barrier layer 431b is 850° C. and above. Preferably, the growth temperature of the third barrier layer 431b is highest, and the third barrier layer 431b grown at high temperature can ensure better quality of the V-pit 31. Further preferably, during the process of growing the third barrier layer 431b, a larger flow rate of hydrogen can be introduced, and an atmosphere of high concentration of hydrogen is more conducive to repairing the V-pit 31.

Next, dry etching is used to etch the second semiconductor layer 50 to the first semiconductor layer 20 to expose part of the surface of the first semiconductor layer 20 to form the mesa structure (MESA).

The mesa structure includes the lower mesa 61 and the upper mesa 62, the lower mesa 61 is the upper surface of the exposed portion of the first semiconductor layer 20, and the upper mesa 62 is the upper surface of the second semiconductor layer 50. In some embodiments, the formation of the mesa structure is not limited to the dry etching.

Finally, the first electrode 71 is formed on the lower mesa 61 so that the first electrode 71 is in direct contact with the first semiconductor layer 20 to form an electrical connection; the second electrode 72 is formed on the upper mesa 62 so that the second electrode 72 is in direct contact with the second semiconductor layer 50 to form an electrical connections, thereby to obtain the LED.

A second embodiment of the disclosure provides another LED. An epitaxial structure 1 of the LED includes a first semiconductor layer 20, a V-pit formation layer 30, a light-emitting layer 40 and a second semiconductor layer 50. This embodiment has many identical features with the first embodiment. The identical features will not be described one by one here, but only the differences will be described.

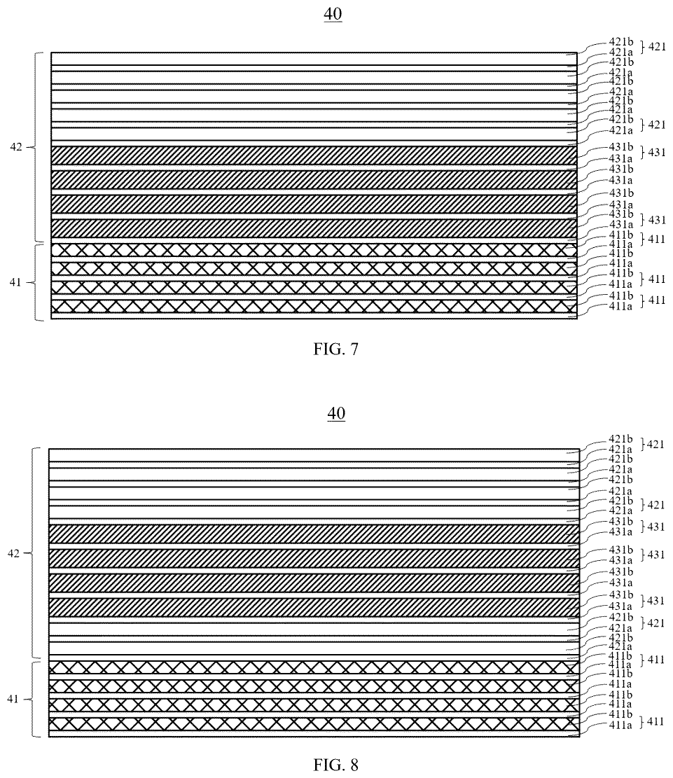

The main difference between this embodiment and the first embodiment is that the second light-emitting layer 42 includes n2 periods of a second quantum well structure 421 and m periods of a third quantum well structure 431, and the first light-emitting layer 41 only includes n1 periods of a first quantum well structure 411, as illustrated in FIGS. 7 and 8.

In this embodiment, a thickness of the single period of the third quantum well structure 431 is greater than a thickness of the single period of the second quantum well structure 421. The main function of the third quantum well structure 431 is used to repair the quality of the V-pit 31 to reduce the probability of non-radiative recombination. Setting the thicker third quantum well structure 431 is more conducive to improving the quality of the V-pit 31.

In some embodiments, the m periods of the third quantum well structure 431 may be disposed between two second quantum well structures 421 or between the first quantum well structure 411 and the second quantum well structure 421, please refer to FIGS. 7 and 8 for details. Similarly, it is preferable that the m periods of the third quantum well structure 431 are still arranged continuously rather than at intervals.

Affected by the special transport mechanism of carriers (electrons and holes), the second light-emitting layer 42, especially 1 to 4 periods of the quantum well structure closest to the second semiconductor layer 50, serves as the main light-emitting area. As the quantum well structure that mainly emits light, it cannot have a thicker thickness. Therefore, at least 1 to 4 periods of the quantum well structure closest to the second semiconductor layer 50 need to be the second quantum well structure rather than the third quantum well structure. That is, there are at least 4 periods of the second quantum well structure 421 between the third quantum well structure 431 and the second semiconductor layer 50 to avoid the large light absorption caused by setting the thicker third quantum well structure as the main light-emitting structure. Moreover, when the 1 to 4 periods of the quantum well structure closest to the second semiconductor layer 50 are the third quantum well structures, they are too far away from the V-pit formation layer 30 and the V-pit 31 cannot be repaired in time, resulting in poor repair effect. Therefore, it is preferable that the third quantum well structure 431 is disposed facing away from the second semiconductor layer 50 and close to the first light-emitting layer 41 to ensure that the V-pit 31 with better quality is obtained. Further preferably, the third quantum well structure 431 is in direct contact with the first light-emitting layer 41, that is, the third quantum well structure 431 is closer to the first quantum well structure 411 (first light-emitting layer 41) than the second quantum well structure 421, please refer to FIG. 7 for details.

Further, the first quantum well structure 411 includes a first well layer 411a and a first barrier layer 411b, the second quantum well structure 421 includes a second well layer 421a and a second barrier layer 421b, and the third quantum well structure 431 includes a third well layer 431a and third barrier layer 431b.

In some embodiments, a thickness of each of the first well layer 411a, the second well layer 421a, and the third well layer 431a is in the range of 20 Å to 50 Å, and a thickness of each of the first barrier layer 411b, the second barrier layer 421b and the third barrier layer 431b is in the range of 80 Å to 140 Å. Preferably, the thicknesses of the first well layer 411a, the second well layer 421a and the third well layer 431a are set to be same to avoid defects of different wavelengths caused by different thicknesses of the well layers, while the first barrier layer 411b, the second barrier layer 421b and the third barrier layer 431b can be set to different thicknesses, the thickness of the third barrier layer 431b is greater than the thickness of the second barrier layer 421b, which can better improve the quality of the V-pit 31 by setting the thicker third barrier layer 431b. Preferably, the thickness of the second barrier layer 421b is in the range of 80 Å to 110 Å, and the thickness of the third barrier layer 431b is in the range of 110 Å to 140 Å. More preferably, the thickness of the third barrier layer 431b is 1.1 to 1.5 times the thickness of the second barrier layer 421b.

In some embodiments, the period numbers of the first quantum well structure 411, the second quantum well structure 421 and the third quantum well structure 431 are same or different, and the period numbers of the first quantum well structure 411, the second quantum well structure 421 and the third quantum well structure 431 are integer. Preferably, the period number n1 of the first quantum well structure 411 is in the range of 2 to 8, the period number n2 of the second quantum well structure 421 is in the range of 4 to 7, and the period number m of the third quantum well structure 431 is in the range of 1 to 7. Further preferably, a sum of the period number n2 of the second quantum well structure 421 and the period number m of the third quantum well structure 431 is not less than 8, that is, n2+m≥8. More preferably, the period number m of the third quantum well structure 431 is not greater than the period number n2 of the second quantum well structure 421, that is, m≤n2, or in other words, the number of the third quantum well structures 431 cannot exceed half of the number of all quantum well structures in the second light-emitting layer 42.

The materials of each barrier layer and each well layer in the light-emitting layer 40 are basically the same as those in the first embodiment. The only difference is that the In content of the second well layer 421a and the In content of the third well layer 431a are same, and the In content of the first well layer 411a is lowest. In this embodiment, the specific structures of the mesa structure and electrode structure, and beneficial effects of the LED are also the same as those in the first embodiment, and will not be described again here.

The high-quality V-pit 31 can make the LED have higher brightness. The performance of the LED in the related art and the performance of the LED with the light-emitting layer 40 shown in FIG. 7 were tested. Under the same test conditions, the luminous brightness of the LED in the related art was 258.2 milliwatts (mw), while the luminous brightness of the LED according to the embodiment of the disclosure is 260.7 mw, and its brightness can be improved by nearly 1%.

An embodiment of the disclosure further provides a method for preparing the LED according to the second embodiment.

First, the epitaxial structure 1 is provided, which specifically includes the following steps: providing the substrate 80, and sequentially growing the first semiconductor layer 20, the V-pit formation layer 30, the light-emitting layer 40 and the second semiconductor layer 50 on the substrate 80.

The light-emitting layer 40 includes the first light-emitting layer 41 and the second light-emitting layer 42 grown sequentially. The first light-emitting layer 41 includes the n1 periods of the first quantum well structure 411, and the second light-emitting layer 42 includes the n2 periods of the second quantum well structure 421 and the m periods of the third quantum well structure 431. The first quantum well structure 411 includes the first well layer 411a and the first barrier layer 411b grown sequentially, the second quantum well structure 421 includes the second well layer 421a and the second barrier layer 421b grown sequentially, and the third quantum well structure 431 includes the third well layer 431a and the third barrier layer 431b grown sequentially.

During the process of growing the second light-emitting layer 42, all of the third quantum well structures 431 may be grown first, and then all of the second quantum well structures 421 may be grown, or part of the second quantum well structures 421 may be grown first, then all of the third quantum well structures 431 are grown, and finally the remaining second quantum well structures 421 are grown. The thickness of the single third quantum well structure 431 is greater than the thickness of the single second quantum well structure 421.

The growth method and other conditions of the first semiconductor layer 20, the V-pit formation layer 30, the light-emitting layer 40 and the second semiconductor layer 50 are the same as the method for preparing the LED in the first embodiment, and will not be described again here.

An embodiment of the disclosure further provide a light-emitting device. The light-emitting device adopts the LED provided in any of the above embodiments, and its specific structure and technical effects will not be described again.

The size of the LED can be Micro LED, Mini LED or regular LED. The LED can be used in backlight displays or RGB displays. LEDs with small-sized flip-chip structures can be integrated into an application substrate or a packaging substrate in hundreds, thousands, or tens of thousands to form a light-emitting source part of backlight display devices or RGB display devices.

What is claimed is:

1. A light-emitting diode (LED), comprising:
a first semiconductor layer;
a V-pit formation layer, located on the first semiconductor layer, and the V-pit formation layer defining an upwardly extending V-pit;
a light-emitting layer, located on the V-pit formation layer; and
a second semiconductor layer, located on the light-emitting layer and filling the V-pit;
wherein the light-emitting layer comprises:
a first light-emitting layer, the first light-emitting layer comprising n1 periods of a first quantum well structure and m periods of a third quantum well structure, wherein a thickness of a single period of the third quantum well structure is greater than a thickness of a single period of the first quantum well structure; and
a second light-emitting layer, the second light-emitting layer being closer to the second semiconductor layer than the first light-emitting layer, and the second light-emitting layer comprising n2 periods of a second quantum well structure.

2. The LED as claimed in claim 1, wherein the m periods of the third quantum well structure are arranged continuously rather than at intervals.

3. The LED as claimed in claim 1, wherein the first quantum well structure comprises a first well layer and a first barrier layer, the second quantum well structure comprises a second well layer and a second barrier layer, the third quantum well structure comprises a third well layer and a third barrier layer, and a thickness of the third barrier layer is greater than a thickness of the first barrier layer.

4. The LED as claimed in claim 3, wherein the thickness of the first barrier layer is in a range of 80 angstroms (Å) to 110 Å, and the thickness of the third barrier layer is in a range of 110 Å to 140 Å.

5. The LED as claimed in claim 3, wherein the thickness of the third barrier layer is 1.1 to 1.5 times the thickness of the first barrier layer.

6. The LED as claimed in claim 1, wherein the period number n1 of the first quantum well structure is in a range of 1 to 4, the period number n2 of the second quantum well structure is in a range of 8 to 13, and the period number n3 of the third quantum well structure is in a range of 1 to 4.

7. The LED as claimed in claim 1, wherein the period number m of the third quantum well structure is not greater than the period number n1 of the first quantum well structure.

8. The LED as claimed in claim 3, wherein the first well layer, the second well layer, and the third well layer all comprises an indium (In) material, In content of the first well layer and In content of the second well layer are same, and In content of the third well layer is highest.

9. A LED, comprising:
a first semiconductor layer;
a V-pit formation layer, located on the first semiconductor layer, and the V-pit formation layer defining an upwardly extending V-pit;
a light-emitting layer, located on the V-pit formation layer; and
a second semiconductor layer, located on the light-emitting layer and filling the V-pit;
wherein the light-emitting layer comprises:
a first light-emitting layer, comprising n1 periods of a first quantum well structure;
a second light-emitting layer, closer to the second semiconductor layer than the first light-emitting layer, comprising n2 periods of a second quantum well structure and m periods of a third quantum well structure, wherein a thickness of a single period of the third quantum well structure is greater than a thickness of a single period of the second quantum well structure.

10. The LED as claimed in claim 9, wherein the m periods of the third quantum well structure are arranged continuously rather than at intervals.

11. The LED as claimed in claim 9, wherein the first quantum well structure comprises a first well layer and a first barrier layer, the second quantum well structure comprises a second well layer and a second barrier layer, the third quantum well structure comprises a third well layer and a third barrier layer, and a thickness of the third barrier layer is greater than a thickness of the second barrier layer.

12. The LED as claimed in claim 11, wherein the thickness of the second barrier layer is in a range of 80 Å to 110 Å, and the thickness of the third barrier layer is in a range of 110 Å to 140 Å.

13. The LED as claimed in claim 11, wherein the thickness of the third barrier layer is 1.1 to 1.5 times the thickness of the second barrier layer.

14. The LED as claimed in claim 9, wherein the period number n1 of the first quantum well structure is in a range of 2 to 8, the period number n2 of the second quantum well structure is in a range of 4 to 7, and the period number m of the third quantum well structure is in a range of 1 to 7.

15. The LED as claimed in claim 9, wherein a sum of the period number n2 of the second quantum well structure and the period number m of the third quantum well structure is not less than 8.

16. The LED as claimed in claim 9, wherein the period number m of the third quantum well structure is not greater than the period number n2 of the second quantum well structure.

17. The LED as claimed in claim 9, wherein the m periods of the third quantum well structure are arranged facing away from the second semiconductor layer and closer to the first light-emitting layer.

18. The LED as claimed in claim 9, wherein at least four periods of the n2 periods of the second quantum well structure are located between the third quantum well structure and the second semiconductor layer.

19. The LED as claimed in claim 11, wherein the first well layer, the second well layer, and the third well layer all comprises an In material, In content of the second well layer and In content of the third well layer are same, and In content of the first well layer is lowest.

20. A light-emitting device, comprising the LED as claimed in claim 1.
